(19) United States
(12) Patent Application Publication
(10) Pub. No.: US 2003/0057807 A1
(43) Pub. Date: Mar. 27, 2003

(54) Vibrational damping apparatus and method for deriving a digital signal processing algorithm

(76) Inventors: Andrew Fleming, Merewether (AU); Sam Behrens, Warabrook (AU); Reza Moheimani, Callaghan (AU)

Correspondence Address: PILLSBURY WINTHROP, LLP, P.O. BOX 10500, MCLEAN, VA, 22102, US

(21) Appl. No.: 10/295,822

(22) Filed: Nov. 18, 2002

Related U.S. Application Data
(63) Continuation of application No. PCT/AU01/00566, filed on May 17, 2001.

(30) Foreign Application Priority Data
May 17, 2000 (AU) PQ 7559

(51) Int. Cl. H02N 2/00; H01L 41/04

(52) U.S. Cl. 310/326; 310/311

(57) ABSTRACT

A first impedance synthesizing arrangement is adapted to accept an input voltage and to provide a corresponding output current according to a predefined relationship between the input voltage and the output current. A second impedance synthesizing arrangement accepts an input current and provides an output voltage. The first and second impedance synthesizing arrangements may be utilized in the vibrational damping apparatus. When using a digital signal processor in the impedance synthesizing arrangement, it is preferable to develop an algorithm which can be used to ensure that the predefined relationship between the voltage and the current is as required. A preferred method for deriving a digital signal processing algorithm includes designing a shunt circuit having a plurality of impedances which, in combination with any inherent capacitance of the piezoelectric component, would give desired vibrational damping properties; converting the shunt circuit into a transfer function block diagram; and forming a digital signal processing algorithm from the block diagram.

### CROSS-REFERENCE TO RELATED APPLICATIONS

This application is a continuation application of PCT/AU01/00566 filed on May 17, 2001, pending, which in turn claims priority to Australian application no. PQ 7559 filed May 17, 2000, the contents of both of which are incorporated by reference in their entirety.

### BACKGROUND OF THE INVENTION

1. Technical Field of the Invention

The invention has been developed primarily for use in the field of piezoelectric vibrational damping and will be described hereinafter with reference to this application. However, it will be appreciated that the invention is not limited to this particular field of use.

2. Description of Related Art

Prior art analog circuitry utilizing components such as resistors, capacitors, inductors etc. can suffer from a number of disadvantages such as excessive circuit complexity, component cost and suboptimal performance if the temperature of the components exceeds ordinary operating limits.

It has been appreciated by the inventors of the present invention that such disadvantages apply to prior art vibrational damping arrangements utilizing passively shunted piezoelectric material. An example of such prior art is provided by the journal article entitled “Damping of Structural Vibrations with Piezoelectric Materials and Passive Electrical Networks” (N. W. Hagood and A. von Flotow, Journal of Sound and Vibration, 146 (2) 243-268), the contents of which are hereby incorporated in their entirety by reference.

It will be appreciated by those skilled in the art that a further disadvantage associated with the damping arrangement disclosed by the Hagood article is that only one of the modes of vibration of the structure is damped. This is partially addressed by U.S. Pat. No. 5,783,898 which discloses an arrangement which can damp more than one mode of vibration. However it has been appreciated by the inventors that there are a number of problems with this technique, the foremost being the complexity and size of the circuit required to implement the total impedance. Typically the shunt circuits contain up to 48 opamps for a three mode circuit and require large inductor values, which may be up to hundreds of Henries. The more modes that are shunted, the greater the number of opamps required. Virtual grounded inductors and virtual floating inductors (Riordan gyrators) are required to implement the grounded and floating inductor elements. These circuits are typically poor representations of ideal inductors, are large in size, and are sensitive to component tolerances and non-ideal characteristics.

Piezoelectric patches are capable of generating hundreds of volts for moderate structural excitations and this requires the entire shunt circuit to be constructed from high voltage components, with significant associated component cost. Further voltage limitations arise due to the internal gains in the virtual inductor circuits.

Further, assuming ideal components, there is a fundamental limitation in using the blocking circuit technique taught by said US patent. It is desired to design each parallel shunt branch so that it is only significant over the narrow frequency band of its corresponding structural resonant mode. For two mode damping it is sufficient to assume the current blocker circuit has little effect on the dynamics of the desired R-L shunt circuit around the modal frequency and that the branch will not effect other branches designed for higher resonant frequencies. For this case a 3 dB to 6 dB damping performance penalty is encountered. For a three mode circuit, some or all of the branches would require a series combination of three current blocker circuits This would severely limit the damping performance at each mode in comparison with single mode damping.

Finally, the shunt circuit disclosed in U.S. Pat. No. 5,783,898 must be accurately tuned to each of the frequencies of the modes of vibration that are to be damped. As the prior art circuit componentry heats up, the circuit may effectively be de-tuned due to suboptimal performance of the components, and the inherent tolerances in specification of components such as capacitors and resistors. This may result in significantly less effective damping of one or more modes of structural vibrations.

Any discussion of the prior art throughout the specification should in no way be considered as an admission that such prior art is widely known or forms part of common general knowledge in the field.

### SUMMARY OF THE INVENTION

It is an aspect of the present invention to overcome or ameliorate at least one of the disadvantages of the prior art, or to provide a useful alternative.

According to a first aspect of the invention there is provided a vibrational damping apparatus including:

a piezoelectric component to engage with a structure to be vibrationally damped, the piezoelectric component having a pair of electrical terminals for communication of a voltage across the piezoelectric material; and

an impedance synthesizing arrangement configured to accept an input voltage and to provide a corresponding output current according to a predefined relationship between the input voltage and the output current, wherein said predefined relationship is adapted to synthesize a shunting circuit;

the terminals of said piezoelectric component being electrically connected to the impedance synthesizing arrangement such that the input voltage is provided by said piezoelectric material in response to vibration of the structure and the output current is fed to said piezoelectric material so as to vibrationally damp said structure.

According to a second aspect of the invention there is provided a vibrational damping apparatus including:

a piezoelectric component to engage a structure to be vibrationally damped, the piezoelectric component having a pair of electrical terminals for communication of a voltage across the piezoelectric material; and

an impedance synthesizing arrangement configured to accept an input current and to provide a corresponding output voltage according to a predefined relationship between the input current and the output voltage, wherein said predefined relationship is adapted to synthesize a shunting circuit;

the terminals of said piezoelectric component being electrically connected to the impedance synthesizing arrangement such that the input current is provided by said piezoelectric material in response to vibration of the structure and the output voltage is fed to said piezoelectric material so as to vibrationally damp said structure.

In one preferred embodiment the impedance synthesizing arrangement includes a digital signal processor and in another embodiment it includes analog circuitry to define the said voltage—current relationship.

According to another aspect of the invention there is provided a method for deriving a digital signal processing algorithm to be utilized in the vibrational damping apparatus described above, said method including:

1) designing a shunt circuit having a plurality of impedances which, in combination with any inherent capacitance of the piezoelectric component, would give desired vibrational damping properties;

2) converting said shunt circuit into a transfer function block diagram; and

3) forming a digital signal processing algorithm from said block diagram.

As used in the present patent specification, the terms “impedance synthesis”, “impedance synthesizing”, and the like, are to be construed in the sense of providing an alternative to prior art methods for implementing an impedance. For example, if a prior art specific arrangement of electrical components is disposed at a given location within an electrical circuit so as to provide a required impendence, then synthesis of the required impendence involves utilization of the impedance synthesizing arrangement according to the present invention in the place of said specific arrangement of electrical components. Of course, it is to be understood in such a context that the impedance synthesizing arrangement will differ from the specific arrangement of electrical components.

These and other aspects will be described in or apparent from the following description of the preferred embodiments.

### BRIEF DESCRIPTION OF THE DRAWINGS

Preferred embodiments of the invention will be described, by way of example only, with reference to the accompanying drawings, in which:

FIG. 1 is a circuit diagram illustrating the functionality of a first embodiment of an impedance synthesizing arrangement;

FIG. 2 is a circuit diagram illustrating a vibrational damping apparatus utilizing the first embodiment of the impedance synthesizing arrangement;

FIG. 3 is a circuit diagram illustrating a piezoelectric material connected to a first shunt circuit;

FIG. 4 is a circuit diagram illustrating a piezoelectric material connected to a second shunt circuit;

FIG. 5 is a circuit diagram illustrating a piezoelectric material connected to a third shunt circuit;

FIG. 6 illustrates a parallel network of impedances and the equivalent transfer function block diagram;

FIG. 7 illustrates a series network of impedances and the equivalent transfer function block diagram;

FIG. 8 is a graph illustrating the results of an experiment to compare undamped vibrations with vibrations damped using a preferred embodiment of the improved vibrational damping apparatus;

FIG. 9 is a circuit diagram illustrating the functionality of a second embodiment of an impedance synthesizing arrangement; and

FIG. 10 is a circuit diagram illustrating a shunt circuit being synthesized by the second embodiment of an impedance synthesizing arrangement for connection to a piezoelectric material.

### DETAILED DESCRIPTION OF PREFERRED EMBODIMENTS

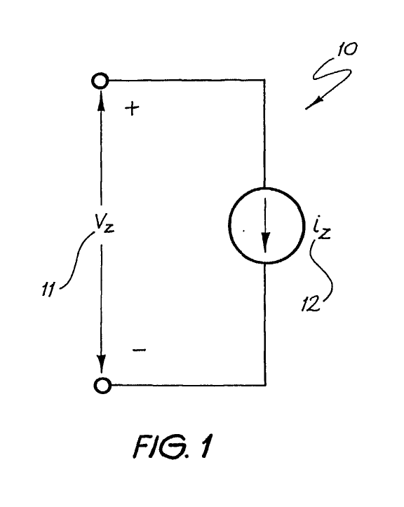

Referring to the drawings, the functionality of a first embodiment of an impedance synthesizing arrangement is illustrated in FIG. 1. The impedance synthesizing arrangement, shown schematically as reference numeral 10, is adapted to accept an input voltage 11 and to provide a corresponding output current 12 according to a predefined relationship between the input voltage and the output current. In mathematical terms:

i_{z}(t)=f{v(t)}

where the function f is the “predefined relationship” which can be made to synthesize a network of physical components, for example by fixing i_{z} to be the output of a linear transfer function of v_{z} in the LaPlace domain, i.e.,

I_{z}(s)=Y(s)V_{z}(s),

where

Y(s)=1/Z(s)

and Z(s) is the impedance to be seen from the terminals.

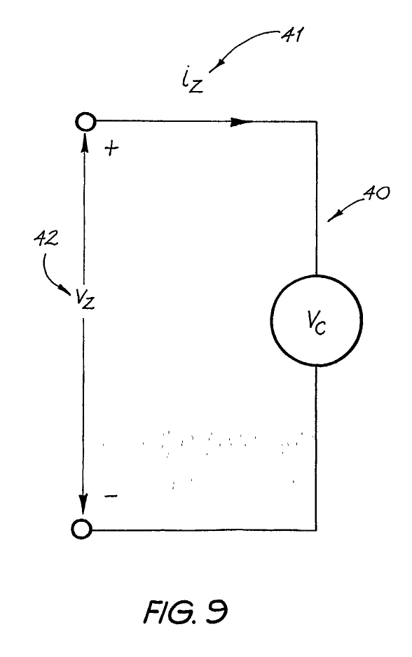

FIG. 9 illustrates another embodiment of an impedance synthesizing arrangement 40 adapted to accept an input current i_{z} 41 and to provide a corresponding output voltage v_{z} 42 according to a predefined relationship between the input current i_{z} 41 and the output voltage v_{z} 42. In mathematical terms as expressed in the time domain:

v_{z}(t)=f{i_{z}(t)}

where the function f is a “predefined relationship” which can be made to synthesize a network of physical components as discussed above.

Alternatively, as expressed in the LaPlace domain:

V_{z}(s)=Z(s)I_{z}(s),

where Z(s) is the impedance to be synthesized.

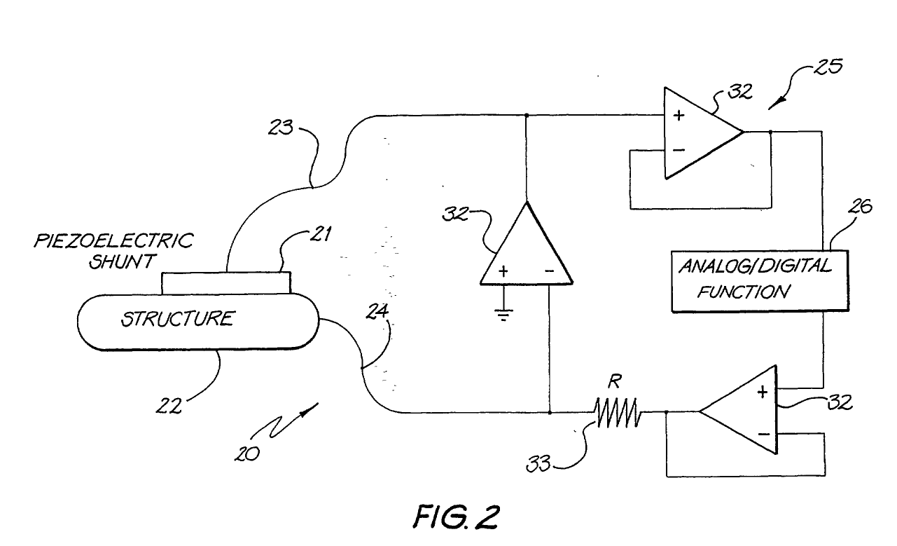

Referring now to the vibrational damping apparatus 20 shown in FIG. 2, the piezoelectric component 21 is engaged with a structure 22 which is to be vibrationally damped. In some embodiments the piezoelectric component 21 is bonded to the structure 22 with a thin layer of adhesive epoxy, although other methods of engagement may be used. Clearly the piezoelectric material should be placed at or near a vibrational antinode for maximum vibrational damping efficiency, although other positions may suffice for certain purposes. The piezoelectric component 21 has a pair of electrical terminals 23 and 24 for communication of a voltage across the piezoelectric material.

The impedance synthesizing arrangement 25 utilized in the vibrational damping arrangement 20 may include an analog or preferably digital module 26 to implement a transfer function. The predefined relationship provided by the transfer function is adapted to synthesize a circuit for passive shunting of the piezoelectric material 21.

The terminals 23, 24 of the piezoelectric component 21 are electrically connected to the impedance synthesizing arrangement 25 such that the input voltage 11 is provided by the piezoelectric material 21 in response to vibration of the structure 22 and the output current 12 is fed to the piezoelectric material 21 so as to vibrationally damp the structure.

The module 26 for implementing a transfer function which is part of the impedance synthesizing arrangement 25 is preferably a digital signal processor, although in some embodiments may be an analog circuit.

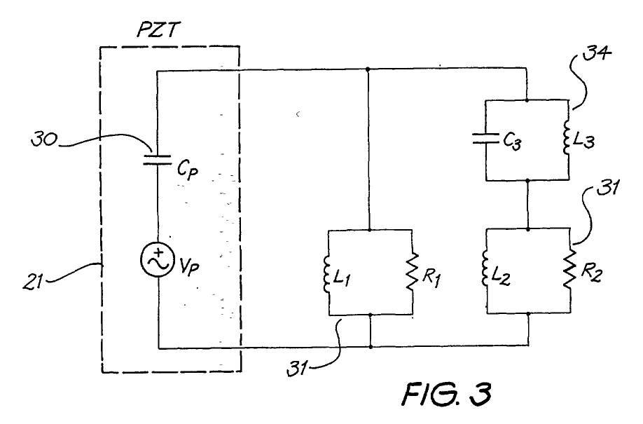

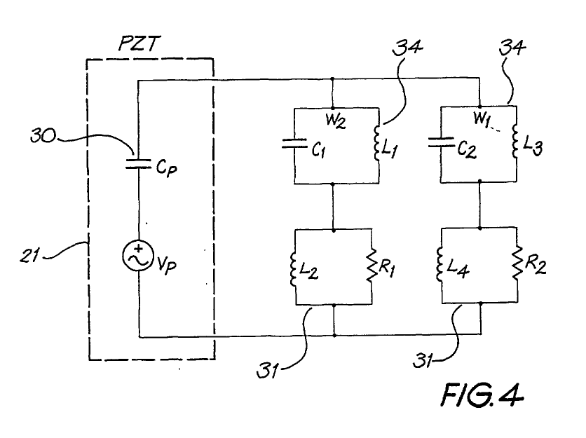

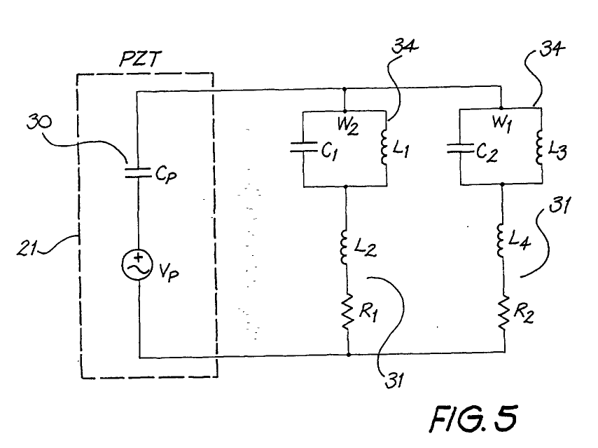

Some of the possible shunting circuits which may be synthesized by the impedance synthesizing arrangement 25 are shown in FIGS. 3, 4 and 5. More particularly, the circuit which is synthesized by the impedance synthesizing arrangement 25 is the circuit minus the piezoelectric component 21 (also labelled PZT), to which the impedance synthesizing arrangement 25 is electrically connected. These shunting circuits, in combination with any inherent capacitance 30 of the piezoelectric component, are tailored to result in an impedance experienced by the piezoelectric material 21 which has a first local maximum at a frequency substantially equal to a first resonant frequency of a first mode of vibration of the structure. In other words, if one of the modes of vibration to be damped occurs at, say, 74.6 Hz then the impedance experienced by the piezoelectric material 21 is tailored to have a local maximum at 74.6 Hz. If it is desired to vibrationally damp more than one mode, the shunting circuit synthesized by said impedance synthesizing arrangement 25, in combination with any inherent capacitance 30 of the piezoelectric component 21, is tailored to result in an impedance which has local maxima at frequencies substantially equal to resonant frequencies of modes of vibration of the structure. For example, if two of the modes of vibration to be damped occur at, say, 74.6 Hz and 171.4 Hz, then the impedance experienced by the piezoelectric material 21 is tailored to have local maxima at 74.6 Hz and 171.4 Hz.

As can be best seen from FIGS. 3, 4 and 5, the shunting circuits synthesized by the impedance synthesizing arrangement 25, in combination with any inherent capacitance 30 of the piezoelectric component 21, have the effect of one or more L-C-R circuits 31, each tuned to resonate at different resonant frequencies of modes of vibration of the structure 22. More particularly, the shunt circuits include a plurality of such L-C-R circuits 31, at least some of which are subject to a blocking component 34 adapted to ensure that substantially only the respective resonant frequency is fed to each L-C-R circuit. In other words, if one L-C-R circuit 31 is tuned for a maximum impedance at, say, 74.6 Hz, then its blocking component 34 ensures substantially only that frequency is fed to that L-C-R circuit 31.

The blocking component 34 used in the circuits shown in FIGS. 3, 4 and 5 are L-C circuits tuned to anti-resonate as required for blockage purposes.

As shown in FIG. 2, three opamps 32 and a resistor 33 electrically connect the impedance synthesizing arrangement 25 to the piezoelectric component 21.

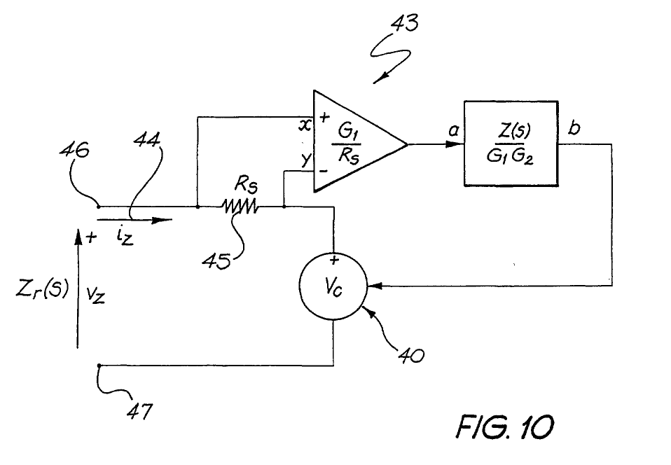

FIG. 10 illustrates an alternative vibrational damping apparatus 43 which utilizes the second embodiment of the impedance synthesizing arrangement 40. V_{c} is a voltage controlled voltage source (non inverting amplifier) with gain G₂. The gains G₁ and G₂ are included to allow magnitude conditioning of the signals a(t) and b(t). This is useful to achieve a maximum signal to noise ratio if a digital signal processor is used to synthesize Z(s). Note that the signal a(t) is equivalent to the volts terminal current in G₁volts/amp.

The terminal current i_{z}(t) 44 is measured, in this case by sensing the voltage across resistor Rs 45, however in alternative embodiments other components, structures, modules, etc., such as a Hall Effect Sensor may be employed to measure the current 44.

$${I}_{z} ( s ) = \frac{X ( s ) - Y ( s )}{{R}_{s}}$$

It follows that:

$${I}_{z} ( s ) = \frac{{V}_{z} ( s )}{Z ( s )} - \frac{{I}_{z} ( s ) R ( s )}{Z ( s )}$$

Thus we arrive at the relationship between terminal voltage and current:

$${Z}_{T} ( s ) = \frac{{V}_{z} ( s )}{{I}_{z} ( s )} = Z ( s ) + {R}_{s}$$

The terminal impedance Z_{T}(S) is equivalent to Z(s)+Rₛ where Z(s) is the impedance transfer function of some electrical network. In use, the terminals 46 and 47 are connectable to piezoelectric material in order to provide vibrational damping.

When using a digital signal processor 26 in the impedance synthesizing arrangement 25, it is preferable to develop an algorithm which can be used to ensure that the predefined relationship between the voltage 11 and the current 12 is as required. The preferred method for deriving a digital signal processing algorithm includes:

1) designing a shunt circuit (for example as illustrated in FIG. 3, 4 or 5) having a plurality of impedances which, in combination with any inherent capacitance 30 of the piezoelectric component 21, would give desired vibrational damping properties;

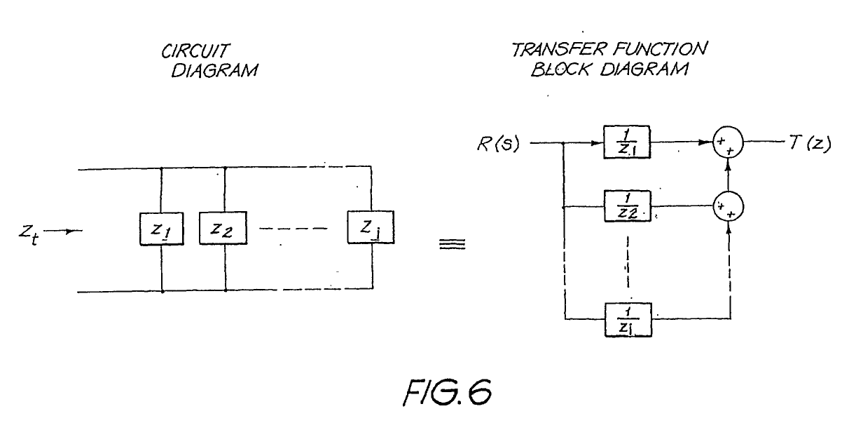

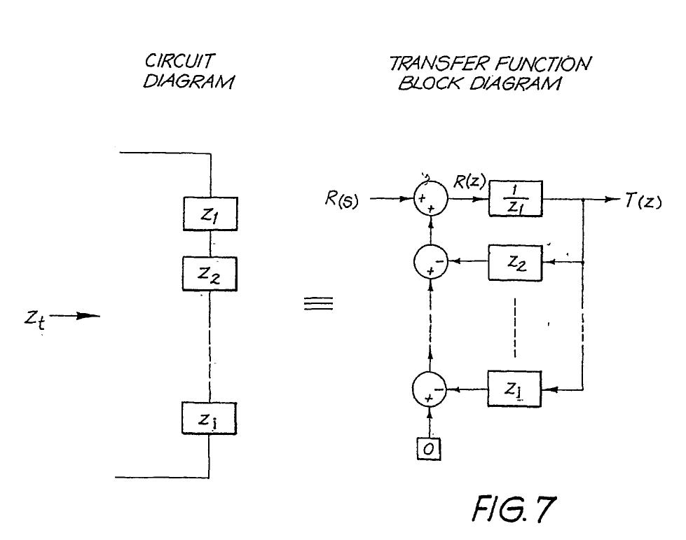

2) converting said shunt circuit into a transfer function block diagram (such as those illustrated in FIGS. 6 and 7);

3) forming a digital signal processing algorithm from said block diagram.

It will be appreciated by those skilled in the art that combinations of the parallel and series arrangements shown in FIGS. 6 and 7 may be used for circuits having combinations of parallel and series impedances.

“Forming a digital signal processing algorithm from said block diagram” is preferably performed by a graphical compilation package, such as the Real Time Workshop for MATLAB, although other methods are known to those skilled in the art.

An alternative to using the “block” method described in the preceding paragraphs is to compute from first principles an overall impedance for the shunt circuit, based upon an analysis of each of the separate components and their interrelationships. This approach has the disadvantage of increased computational difficulty, however has the advantage of not requiring a graphical compilation package or conversion of the shunt circuit into a transfer function block diagram.

Preferred embodiments of the vibrational damping apparatus were built for the purposes of testing. Two structural modes of vibration of a simply supported beam 22 were damped using a simulation of the shunt circuit shown in FIG. 3. The circuit shown in FIG. 2 was used to connect the synthetic impedance arrangement 25 to the piezoelectric component 21. The component values to damp two modes at 74.6 Hz and 171.4 Hz were:

R₁=262.75 kΩ;

R₂=550.73 kΩ;

L₁=42 H;

L₂=20.3 H;

L₃=45.2 H; and

C₃=100 nF.

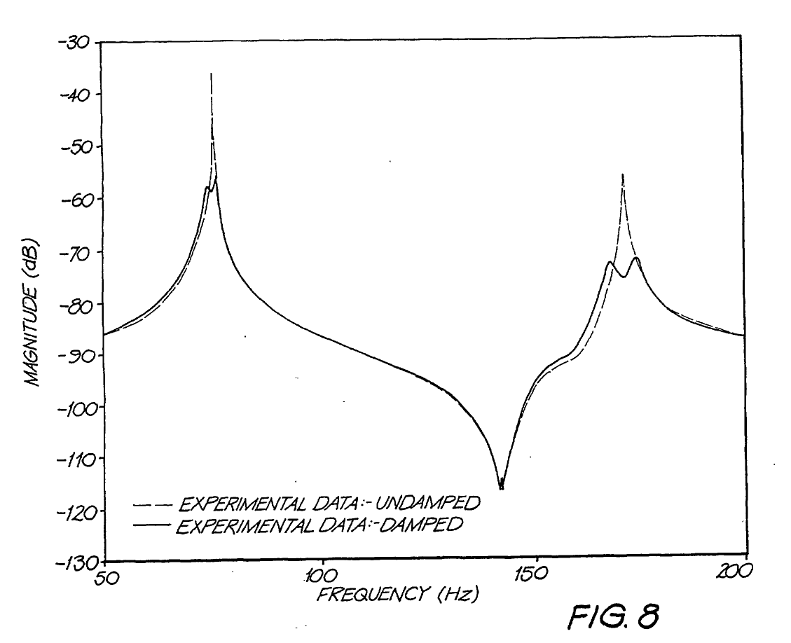

The results are shown in FIG. 8 where the frequency response is measured from the applied structural excitation magnitude to structural velocity magnitude at a point. There was found to be a 20 dB and 18 dB reduction of the two resonant peaks. It was found experimentally that these results were considerably better than those obtained by using the technique taught by U.S. Pat. No. 5,783,898 with the same shunt circuit, even after extensive tuning to calibrate the virtual inductors and branch frequencies.

Additionally, the preferred embodiment of the vibrational damping apparatus 20 may be easily used to damp higher order modes by designing the appropriate damping network and implementing the algorithm derived therefrom.

Although the invention has been described with reference to specific examples, it will be appreciated by those skilled in the art that the invention may be embodied in many other forms.

What is claimed is:

1. A vibrational damping apparatus including:
a piezoelectric component to engage with a structure to be vibrationally damped, the piezoelectric component having a pair of electrical terminals for communication of a voltage across the piezoelectric material; and
an impedance synthesizing arrangement configured to accept an input voltage and to provide a corresponding output current according to a predefined relationship between the input voltage and the output current, wherein said predefined relationship is adapted to synthesize a shunting circuit;
the terminals of said piezoelectric component being electrically connected to the impedance synthesizing arrangement such that the input voltage is provided by said piezoelectric material in response to vibration of the structure and the output current is fed to said piezoelectric material so as to vibrationally damp said structure.

2. A vibrational damping apparatus including:
a piezoelectric component to engage with a structure to be vibrationally damped, the piezoelectric component having a pair of electrical terminals for communication of a voltage across the piezoelectric material; and
an impedance synthesizing arrangement configured to accept an input current and to provide a corresponding output voltage according to a predefined relationship between the input current and the output voltage, wherein said predefined relationship is adapted to synthesize a shunting circuit;
the terminals of said piezoelectric component being electrically connected to the impedance synthesizing arrangement such that the input current is provided by said piezoelectric material in response to vibration of the structure and the output voltage is fed to said piezoelectric material so as to vibrationally damp said structure.

3. A vibrational damping apparatus according to claim 1, wherein said impedance synthesizing arrangement includes a digital signal processor.

4. A vibrational damping apparatus according to claim 1, wherein said impedance synthesizing arrangement includes an analog low pass filter with gain.

5. A vibrational damping apparatus according claim 1, wherein said shunting circuit synthesized by said impedance synthesizing arrangement, in combination with any inherent capacitance of the piezoelectric component, results in an impedance which has a first local maximum at a frequency substantially equal to a first resonant frequency of a first mode of vibration of the structure.

6. A vibrational damping apparatus according to claim 1, wherein said shunting circuit synthesized by said impedance synthesizing arrangement, in combination with any inherent capacitance of the piezoelectric component, results in an impedance which has local maxima at frequencies substantially equal to resonant frequencies of modes of vibration of the structure.

7. A vibrational damping apparatus according to claim 1, wherein said shunting circuit synthesized by said impedance synthesizing arrangement, in combination with any inherent capacitance of the piezoelectric component, has the effect of one or more L-C-R circuits, each tuned to resonate at different resonant frequencies of modes of vibration of the structure.

8. A vibrational damping apparatus according to claim 1, wherein three opamps and a resistor electrically connect the impedance synthesizing arrangement to said piezoelectric component.

9. A vibrational damping apparatus according to claim 2, wherein the impedance synthesizing arrangement is connected to said piezoelectric component.

10. A vibrational damping apparatus according to claim 1, wherein said shunt circuit includes a plurality of L-C-R circuits, each being tuned to resonate at different resonant frequencies of modes of vibration of the structure, at least some of said L-C-R circuits being subject to a blocking component configured to ensure that substantially only the respective resonant frequency is fed to each L-C-R circuit.

11. A vibrational damping apparatus according to claim 2, wherein said impedance synthesizing arrangement includes a digital signal processor.

12. A vibrational damping apparatus according to claim 2, wherein said impedance synthesizing arrangement includes an analog low pass filter with gain.

13. A vibrational damping apparatus according claim 2, wherein said shunting circuit synthesized by said impedance synthesizing arrangement, in combination with any inherent capacitance of the piezoelectric component, results in an impedance which has a first local maximum at a frequency substantially equal to a first resonant frequency of a first mode of vibration of the structure.

14. A vibrational damping apparatus according to claim 2, wherein said shunting circuit synthesized by said impedance synthesizing arrangement, in combination with any inherent capacitance of the piezoelectric component, results in an impedance which has local maxima at frequencies substantially equal to resonant frequencies of modes of vibration of the structure.

15. A vibrational damping apparatus according to claim 2, wherein said shunting circuit synthesized by said impedance synthesizing arrangement, in combination with any inherent capacitance of the piezoelectric component, has the effect of one or more L-C-R circuits, each tuned to resonate at different resonant frequencies of modes of vibration of the structure.

16. A vibrational damping apparatus according to claim 2, wherein said shunt circuit includes a plurality of L-C-R circuits, each being tuned to resonate at different resonant frequencies of modes of vibration of the structure, at least some of said L-C-R circuits being subject to a blocking component configured to ensure that substantially only the respective resonant frequency is fed to each L-C-R circuit.

17. A method for deriving a digital signal processing algorithm to be utilized in the vibrational damping apparatus of claim 1, said method comprising:
1) designing a shunt circuit having a plurality of impedances which, in combination with any inherent capacitance of the piezoelectric component, would give desired vibrational damping properties;
2) converting said shunt circuit into a transfer function block diagram; and
3) forming a digital signal processing algorithm from said block diagram.

18. A method for deriving a digital signal processing algorithm according to claim 17, wherein said forming a digital signal processing algorithm from said block diagram is performed by a graphical compilation package.

19. A method for deriving a digital signal processing algorithm to be utilized in the vibrational damping apparatus of claim 2, said method comprising:
1) designing a shunt circuit having a plurality of impedances which, in combination with any inherent capacitance of the piezoelectric component, would give desired vibrational damping properties;
2) converting said shunt circuit into a transfer function block diagram; and
3) forming a digital signal processing algorithm from said block diagram.

20. A method for deriving a digital signal processing algorithm according to claim 19, wherein said forming a digital signal processing algorithm from said block diagram is performed by a graphical compilation package.
